(19) United States
(12) Patent Application Publication
(10) Pub. No.: US 2008/0082880 A1
(43) Pub. Date: Apr. 3, 2008

(54) METHOD OF TESTING HIGH-SPEED IC WITH LOW-SPEED IC TESTER

(76) Inventors: Hsin-Po Wang, Chu-Tung (TW); Meng-Chyi Lin, Pingjhen City (TW)

Correspondence Address: SMITH-HILL AND BEDELL, P.C., 16100 NW CORNELL ROAD, SUITE 220, BEAVERTON, OR, 97006, US

(21) Appl. No.: 11/470,312

(22) Filed: Sep. 6, 2006

(51) Int. Cl. G01R 31/28

(52) U.S. Cl. 714/731

(57) ABSTRACT

A low-frequency circuit tester tests a high-frequency circuit to determine whether the circuit will operate properly at its specified operating frequency when clocked by a clock signal having a specified period. Each of the first and second phases of the test spans the same number of test cycles, with each test cycle spanning a uniform period exceeding the specified clock period. During each of first and second phases of the test, the circuit tester transmits the same input signal patterns to the circuit and monitors output signal patterns produced by the circuit in response to the input signals. The tester also provides a clock signal for clocking the circuit's logic. During odd-numbered test cycles of the first phase of the test and even-numbered test cycles of the second phase of the test, the tester supplies a pulse of a clock signal to the circuit with a first delay following to the start of the test cycle. During even-numbered test cycles of the first phase of the test, and odd-numbered test cycles of the second phase of the test, the tester supplies a pulse of the clock signal to the circuit with a second delay following the start of the test cycle. The tester adjusts the first and second delays so that if the circuit passes both phases of the test, a test engineer will be able to infer that the circuit will operate at its specified operating frequency.

### BACKGROUND OF THE INVENTION

1. Field of the Invention

The invention relates in general to integrated circuit (IC) test equipment and in particular to a method for testing a high-speed IC using a low-speed IC tester.

2. Description of Related Art

An IC tester tests a digital IC by transmitting input signals to the IC's input terminals and monitoring output signals produced by the IC in response to the input signals to determine whether the output signals behave as expected. FIG. 1 illustrates an I C tester 10 employing one of the more common architectures currently in use, the tester including a set of channels 12, each connected to a separate input/output (IO) terminal of an IC device under test (DUT) 14. Tester 10 organizes a test into a succession of test cycles, and during each test cycle, each channel 12 may either transmit a test signal to a DUT IO terminal or monitor a DUT output signal appearing at the IO terminal to determine whether it behaves as expected. A host computer 16 transmits instructions to each channel 12 via a computer bus 18 to program the channel to carry out its part of the test. During the test, the channels 12 synchronize the timing of their activities to a master clock signal MCLK from a clock source 20

FIG. 2 illustrates a typical internal architecture of one of channels 12. Successive MCLK signal edges mark the start of successive cycles of the test. At the start of each test cycle, as indicated by successive edges of the master clock signal MCLK, a programmable pattern generator 22 produces a data word (VECTOR) indicating the action or actions the channel is to take during the next test cycle. During each test cycle, a formatter circuit 24 decodes the current VECTOR data output of pattern generator 22 to determine how to control signal inputs to a tri-state driver circuit 26 and to a data acquisition circuit 28. When the VECTOR data indicates the channel is to supply a test signal to the DUT during the test cycle, it specifies when the formatter is to output enable tri-state driver 26 and specifies when and how the test signal is to change state during the test cycle. When the VECTOR data indicates that the channel is to monitor a DUT output signal during the test cycle, it specifies when the data acquisition circuit 28 is to sample the DUT output signal and specifies an expected state of the DUT output signal sample. Data acquisition circuit 28 compares the sample state of each DUT output signal to its expected state and stores data indicating the result. A timing signal generator 30 processes the master clock signal MCLK to produce a set of timing signals having same period as the master clock signal but which are evenly distributed in phase so that they divide the test cycle into several time slots. Formatter circuit 24 uses the timing signals as references for timing edges of the control signals it supplies to circuits 26 and 28.

Host computer 16 of FIG. 1 programs pattern generator 22 via instructions supplied through bus 18 and a bus interface circuit 32. Host computer 16 also supplies control data through bus 18 and bus interface 32 to program formatter 24 to decode the VECTOR data, and to program tri-state-driver 26 and data acquisition circuit 28 to operate with the appropriate logic levels. When the test is complete, host computer 16 acquires test results data from data acquisition circuit 28 via bus 1 and bus interface 32.

A digital IC typically uses clocked latches or other clocked devices to coordinate the timing of state changes in the signals passing between various blocks of logic within the IC. FIG. 3 illustrates one commonly used synchronous logic architecture for a DUT 14 wherein two separate clock signals CLK1 and CLK2 supplied by an external source clock two sets of latches 42 and 44 for synchronizing signal communications between logic blocks 40. Logic blocks 40 process their input signals to produce a set of output signals OUT1 supplied as inputs to latches 42, which are clocked by clock signal CLK1. Clock signal CLK2 clocks latches 44, which latch the output signals (OUT2) of latches 42 to produce another set of signals OUT3 supplied as inputs to logic blocks 40. Logic blocks 40 produce their output signals OUT1 and the DUT output signals (OUTPUT) as logical combinations of the OUT3 signals and the IC's input signals (INPUT). During a test, channels of IC tester 10 supply the INPUT, CLK1 and CLK2 signals to DUT 14 and monitor the DUT's OUTPUT signals.

FIG. 4 is a timing diagram illustrating timing relationships between clock signals CLK1 and CLK2 and various internal signals OUT1, OUT2 and OUT3 of DUT 14. IC tester 10 sets the test cycle period as well as the periods of the CLK1 and CLK2 signals to match the DUT's specified operating frequency. In this example, the latches 42 and 44 are input enabled when their clock signals are high and are latched when their clock signals are low. Tester 10 sets the phase of clock signal CLK1 so that the trailing edge of the CLK1 signal causes latches 42 to latch the OUT2 signals during each test cycle when the OUT1 signal is expected to be at a valid logic level. Tester 10 sets the phase of the CLK2 signal so that its trailing edge signals latches 44 to latch the OUT3 signal during each test cycle when the OUT2 is expected to be valid. When DUT 14 is operating properly, the path delay through latches 44 and logic blocks 40 should be less than the time delay (T3-T2) between the trailing edges of the CLK2 and CLK1 signals, and the path delay through latches 42 should be less than the time delay (T2-T1) between trailing edges of the CLK1 and CLK2 signals. By supplying an appropriate INPUT signal pattern to logic blocks 40 and by monitoring the OUTPUT signal pattern the produce, tester 10 can verify the logic blocks 40 implement. Also, by making the delay times (T3-T2) and (T2-T1) sufficiently small, tester 10 can verify that signal path delays through logic blocks 40 and latches 42 and 44 are within specified limits.

Thus to test DUT 14 for both logic and speed using a conventional approach, IC tester 10 should be able to operate with a test cycle frequency matching the specified operating frequency of DUT 14 and should be able to adjust the timing of clock signal edges during each test cycle with sufficiently high accuracy and resolution. Unfortunately, while relatively inexpensive testers can adjust clock signal edges with high accuracy and resolution, they are not able to operate at high frequencies. Referring to FIG. 2, the pattern generator 22 that produces the VECTOR data for controlling channel behavior during each test cycle is often the main impediment to high frequency operation. Since an IC test can span millions of test cycles and since a VECTOR data word is needed for each test cycle, pattern generator 22 requires a large amount of memory to store the data needed to define the VECTOR data sequence it produces during a test. A pattern generator in an inexpensive low-speed IC tester typically employs relatively inexpensive, low-speed memory while a pattern generator in an expensive, high-speed tester employs expensive, high-speed memory. The limited rate at which a pattern generator employing low-speed memory can generate a VECTOR data sequence limits the operating frequency of a low-speed tester. Thus while a low-speed tester can test the logic of a high-speed IC, it is not capable of directly testing the IC at its specified operating frequency.

U.S. Pat. No. 4,477,902 issued Oct. 16, 1984 to Puri et al, discloses a method for using a low-speed tester to test a high speed IC when the IC uses the type of clocking arrangement illustrated in FIG. 3. To test DUT 14 of FIG. 3 at its specified operating frequency using a high-speed tester, the tester must operate with a test cycle period as illustrated in FIG. 4. Puri teaches a method for testing DUT 14 using a low-speed tester that must operate with a longer test cycle period, for example twice as long as the test cycle period of FIG. 4. During a first phase of the test, the edge timing of clock signals CLK1 and CLK2 are as illustrated in FIG. 5, and during a second phase the edge timing of clock signals CLK1 and CLK2 are as illustrated in FIG. 6. Note that during each phase of the test, the test cycle period shown in FIGS. 5 and 6 is twice that of the test cycle period shown in FIG. 4.

In the conventional high-speed test, as illustrated in FIG. 4, the time delay (T2-T1) from each trailing edge of the CLK2 signal to a next trailing edge of the CLK1 signal matches the specified maximum allowable path delay through latches 44 and logic blocks 40. Similarly, the time delay (T3-T2) from each trailing edge of the CLK1 signal to a next trailing edge of the CLK2 signal matches the specified maximum allowable path delay through latches 42. If DUT passes the high-speed test, a test engineer will know that the path delays within the IC are within the specified maximums.

As illustrated in FIG. 5, during the first phase of the low-speed test, the delay (T2-T1) from each trailing edge of the CLK2 to a next trailing edge of the CLK1 signals is set to match the specified maximum allowable path delay through latches 44 and logic blocks 40. Thus if the DUT passes the first phase of the test, a test engineer will know not only that the logic implemented by blocks 40 is correct, but that the total path delay through latches 44 and blocks 40 is within its allowable maximum. On the other hand, the delay (T3-T2) between each trailing edge of the CLK1 signal and a next trailing edge of the CLK2 signal is much longer than the maximum specified path delay through latches 42. The test engineer therefore will not be able to infer from the fact that the DUT passes Phase 1 of the test that the delay through latches 42 is within its maximum allowable limit.

As illustrated in FIG. 6, during the second phase of the low-speed test, the delay (T2-T1) from each trailing edge of the CLK2 to a next trailing edge of the CLK1 signals is much larger than the specified maximum allowable path delay through latches 44 and logic blocks 40. Since the DUT passes Phase 2 of the test, a test engineer will be able to determine that the logic implemented by blocks 40 is correct, and that the signal routing through latches 42 and 44 is correct. The test engineer will not be able to determine that the total path delay through latches 44 and blocks 40 is within its allowable maximum. However, since the delay (T3-T2) between each trailing edge of the CLK1 signal and a next trailing edge of the CLK2 signals matches the maximum specified path delay through latches 42 during Phase 2, the test engineer can infer that the path delay through latches 42 is within its maximum allowable limit when the DUT passes Phase 2.

Accordingly, if the DUT passes both Phase 1 and Phase 2 of the test, the test engineer will know that the IC logic and signal routing are correct and that the path delays through logic blocks 40 and latches 42 and 44 are within their specified maximum limits. Thus the test engineer will be able to infer that the DUT will pass a conventional high-speed test where the DUT is clocked at its specified operating frequency. The method taught by Puri et al therefore enables a low-speed tester to properly test a high-speed DUT of the type employing two separate synchronizing clock signals, even though the low-speed tester cannot operate at a frequency as high as the specified operating frequency of the DUT.

The method taught by Puri et al does not, however, enable a low speed tester to test a high-speed IC DUT of the type that uses only a single synchronizing clock signal. For example, as illustrated in FIG. 7, an IC DUT 48 includes a set of logic blocks 50 which process their input signals to produce a set of output signals OUT1 supplied as inputs to a set of latches 52 clocked by a trailing edge of clock signal CLK1. The leading edge of clock signal CLK1 clocks a set of latches 54 which latch the output signals (OUT2) of latches 52 to produce another set of signals OUT3 supplied as inputs to logic blocks 50. Logic blocks 50 produce their output signals OUT1 and the DUT output signals (OUTPUT) as logical combinations of the OUT3 signals and the IC's input signals (INPUT). During a test, channels of a high-speed IC tester 60 supply the INPUT signals and clock signal CLK1 to DUT 48 and monitor the DUT's OUTPUT signals.

FIG. 8 is a timing diagram illustrating timing relationships between clock signal CLK1 and various internal signals OUT1, OUT2 and OUT3 of DUT 48. The test cycle period and the period of the CLK1 signal are set to match the DUT's specified operating frequency. Tester 60 sets the phase of clock signal CLK1 so that the trailing edge of the CLK1 signal causes latches 52 to latch the OUT2 signals during each test cycle when the OUT1 signal is expected to be at a valid logic level. Tester 60 sets the leading edge of the CLK1 signal so that it signals latches 54 to latch the OUT3 signal during each test cycle when the OUT2 is expected to be valid. When DUT 48 is operating properly, the path delay through latches 54 and logic blocks 50 should be less than the time delay (T3-T2) between the leading and trailing edges of the CLK1 signal, and the path delay through latches 52 should be less than the time delay (T2-T1) between trailing and leading edges of the CLK1 signal. By making the test cycle and delay times (T3-T2) and (T2-T1) sufficiently small, a high-speed tester 60 can verify that signal path delays through logic blocks 50 and latches 52 and 54 are within specified limits when it verifies that the logic of logic blocks 50 is correct.

### BRIEF SUMMARY OF THE INVENTION

The present invention relates to a method for using a low-speed circuit tester to perform a test a high-speed circuit to determine whether the circuit will operate properly at a specified operating frequency when clocked by a clock signal having a specified period, when the tester is not capable of clocking the circuit with the specified period.

During each of first and second phases of the test, the circuit tester transmits input signal patterns to the circuit, monitors output signal patterns produced by the circuit in response to the input signals, and transmits a clock signal to the circuit for clocking the circuit.

Each of the first and second phases of the test spans a plurality of test cycles, with each test cycle spanning a uniform period exceeding the specified clock period. Thus the operating frequency of the circuit tester is lower than the specified operating frequency of the circuit to be tested.

The first and second phases of the test each span N test cycles, 1 through N, where N is an integer greater than 3, and the circuit tester supplies the same input signal patterns to the circuit during both phases of the test. During odd-numbered test cycles of the first phase of the test and even-numbered test cycles of the second phase of the test, the tester supplies a pulse of the clock signal to the circuit with a first delay following to the start of the test cycle. During even-numbered test cycles of the first phase of the test, and odd-numbered test cycles of the second phase of the test, the tester supplies a pulse of the clock signal to the circuit with the second delay following the start of the test cycle. The first and second delays are appropriately selected so that if the circuit passes both phases of the test, a test engineer will be able to infer that the circuit will operate at its specified operating frequency when clocked by a conventional clock signal having the specified period.

The claims appended to this specification particularly point out and distinctly claim the subject matter of the invention. However those skilled in the art will best understand both the organization and method of operation of what the applicant(s) consider to be the best mode(s) of practicing the invention, together with further advantages and objects of the invention, by reading the remaining portions of the specification in view of the accompanying drawing(s) wherein like reference characters refer to like elements.

### BRIEF DESCRIPTION OF THE DRAWING

FIG. 1 depicts in block diagram form, a prior art integrated circuit (IC) tester connected to an IC device under test (DUT).

FIG. 2 depicts one of the channels of the IC tester of FIG. 1 in more detailed block diagram form.

FIG. 3 depicts, in block diagram form, a prior art IC and an IC tester for testing the IC.

FIG. 4 is a timing diagram illustrating timing relationships between signals of the IC of FIG. 3 when the IC tester is programmed to test the IC in a conventional manner.

FIGS. 5 and 6 are timing diagrams illustrating timing relationships between signals of the IC of FIG. 3 when the IC tester is programmed to test the IC in accordance with a prior art method.

FIG. 7 depicts, in block diagram form, a prior art IC and an IC tester for testing the IC.

FIG. 8 is a timing diagram illustrating timing relationships between signals of the IC of FIG. 7 when the IC tester is programmed to test the IC in a conventional manner.

FIGS. 9-11 are timing diagrams illustrating timing relationships between signals of the IC of FIG. 7 when the IC tester is programmed to test the IC employing a method in accordance with the invention.

FIG. 12 is a data flow diagram illustrating a method in accordance with the invention for determining a highest frequency at which each of a set of ICs can operate.

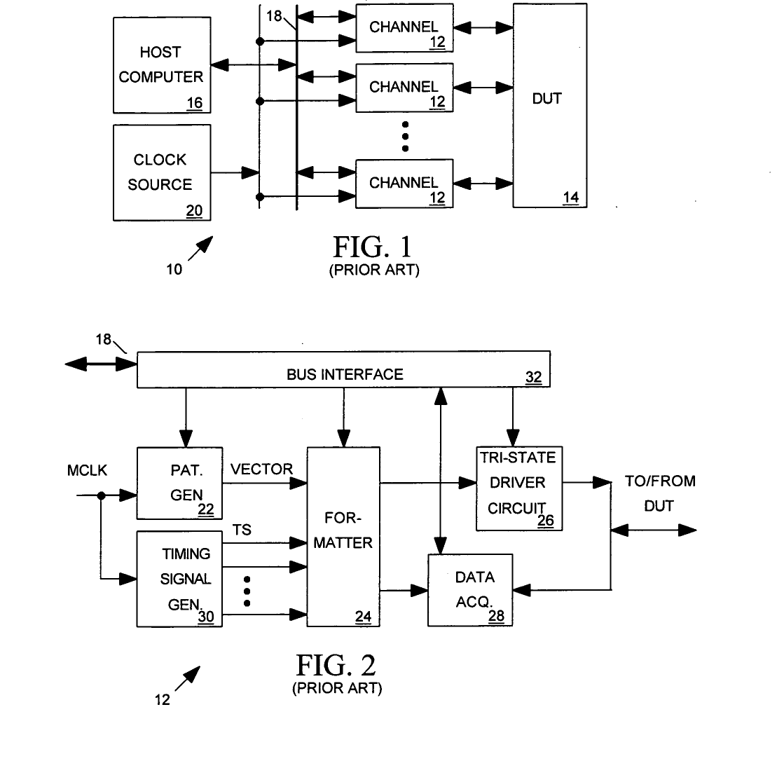

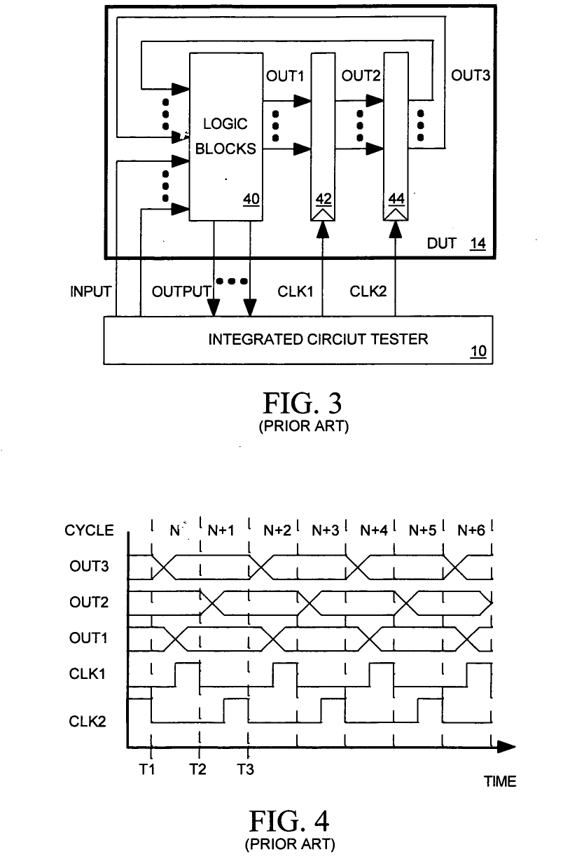

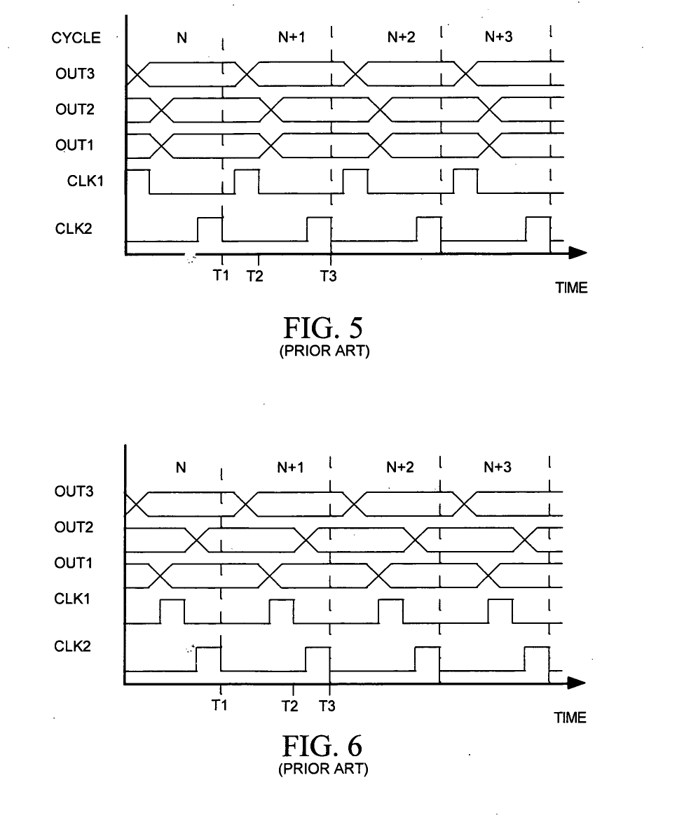

### DETAILED DESCRIPTION OF THE INVENTION

The present invention relates to a method for employing a low-speed tester to test a high-speed integrated circuit (IC). While the specification describes at least one exemplary embodiment of the invention considered a best mode of practicing the invention, the invention is not limited to the particular example(s) described below or to the manner in which they operate.

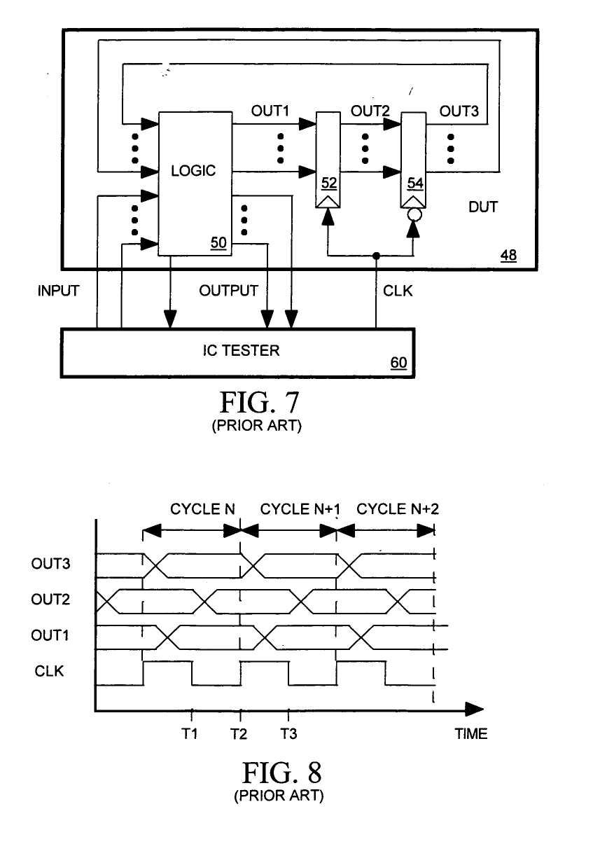

Referring to FIG. 7, a conventional IC tester 60 tests a digital IC device under test (DUT) 48 by transmitting test signals to the DUT's input terminals and monitoring output signals produced by the DUT in response to the test signals to determine whether the output signals behave as expected. DUT 48 includes a set of logic blocks 50 for processing their input signals to produce a set of output signals OUT1 supplied as inputs to a set of latches 52 clocked by a trailing edge of clock signal CLK. The leading edge of clock signal CLK clocks a set of latches 54 which latch the output signals (OUT2) of latches 52 to produce another set of signals OUT3 supplied as inputs to logic blocks 50. Logic blocks 50 produce their output signals OUT1 and the DUT output signals (OUTPUT) as logical combinations of the OUT3 signals and the IC's input signals (INPUT). During a test, tester 60 supplies the INPUT signals and clock signal CLK to DUT 48 and monitors the DUT's OUTPUT signals.

FIG. 8 is a timing diagram illustrating timing relationships between clock signal CLK1 and various internal signals OUT1, OUT2 and OUT3 of DUT 48 when the DUT is tested in a conventional manner by a high-speed tester. Tester 60 sets the test cycle period and the period of the CLK signal to match the DUT's specified operating frequency. During each test cycle the trailing edge of clock signal CLK causes latches 52 to latch the OUT2 signals when the OUT1 signal is expected to be at a valid logic level. The leading edge of the CLK signal causes latches 54 to latch the OUT3 signal during each test cycle when the OUT2 is expected to be valid. When DUT 14 is operating properly, the path delay through latches 54 and logic blocks 50 should be less than the time delay (T3-T2) between the leading and trailing edges of the CLK signal, and the path delay through latches 52 should be less than the time delay (T2-T1) between trailing and leading edges of the CLK signal. By making the test cycle sufficiently short and by making delay times (T3-T2) and (T2-T1) sufficiently small, a high-speed tester 60 can verify that signal path delays through logic blocks 50 and latches 52 and 54 are within specified limits.

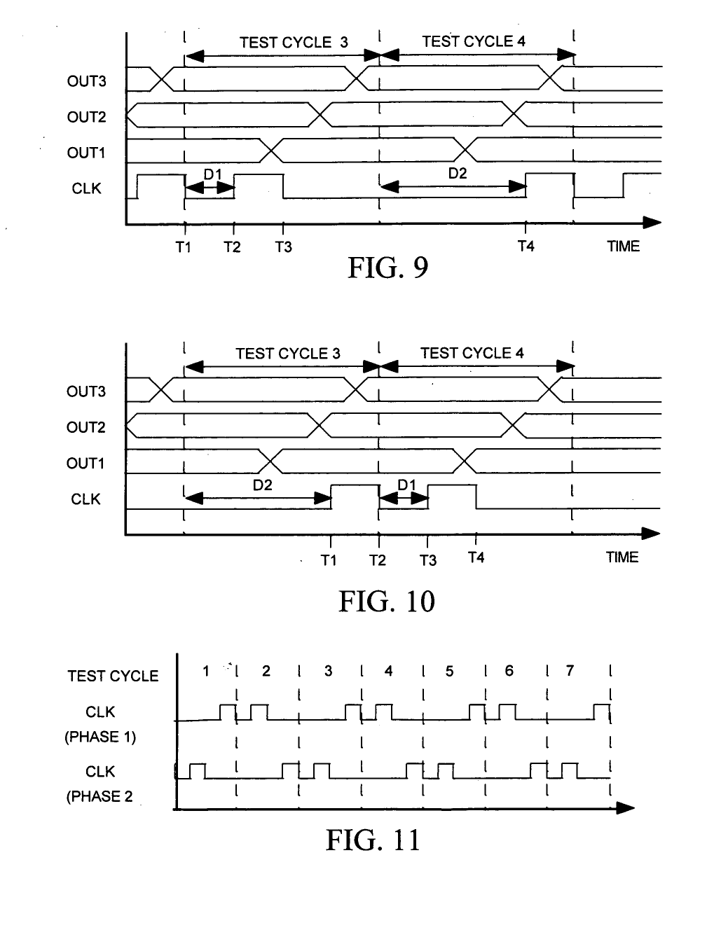

The invention relates to a method for testing a high-speed DUT using a low-speed tester that is not capable of operating with a sufficiently short test cycle and therefore cannot clock the DUT at its specified clock rate. For example, as illustrated in FIGS. 9 and 10, using the method in accordance with the present invention, tester 60 tests DUT 48 using a test cycle having twice the period of the test cycle employed during a conventional high-speed test as illustrated in FIG. 7. The tester carries out the test in two phases, each spanning some number N of test cycles, 1 through N, where N is an integer greater than 2.

FIG. 9 shows signal timing for two cycles (cycles 3 and 4) of Phase 1 of the test and FIG. 10 shows signal timing for two corresponding cycles (cycles 3 and 4) of Phase 2 of the test. FIG. 11 depicts the relationships between the CLK signal timing for seven corresponding cycles of test Phases 1 and 2. During each test phase, tester 60 supplies the same INPUT signal pattern to DUT 48 and expects to see the same OUTPUT signal pattern, but as may be seen from FIGS. 9-11, tester 60 supplies a somewhat different CLK signal pattern during the two test phases. During odd-numbered test cycles of Phase 1 and even-numbered test cycles of Phase 2, tester 60 transmits a pulse of the clock signal to DUT 48 with a first delay D1 following to the start of the test cycle. During even-numbered test cycles of Phase 1 and odd-numbered test cycles of Phase 2, tester 60 transmits a pulse of the clock signal to DUT 48 with the second delay D2 following the start of the test cycle.

Note that during even-numbered cycle of Phase 1 of the test and during each odd-numbered cycle of Phase 2 of the test, the leading edge of the CLK signal pulse follows the trailing edge of the preceding CLK signal pulse by the specified maximum allowable delay through latches 54 and blocks 50. Thus if DUT 60 passes Phase 1 of the test, a test engineer can infer not only that logic blocks 50 carry out the correct during all test cycles, but that the path delay though latches 54 and logic blocks 50 was within the specified limit during all even-numbered phases of the test. If DUT 60 passes Phase 2 of the test, the test engineer can also infer not only that logic blocks 50 carry out the correct during all test cycles, but that the path delay through latches 54 and logic blocks 50 was within the specified limit during all odd-numbered phases of the test. During each test phase, tester 60 sets the pulse width (T3-T2) of the CLK signal to match the specified maximum allowable path delay through latches 52 of FIG. 7 so that if DUT 48 passes both phases of the test, a test engineer can infer that the path delay through latches 52 is within its specified allowable maximum.

Thus if DUT 60 passes both phases of the low-speed test performed with tester 60 operating at a test cycle frequency lower than the specified operating frequency of the DUT, the test engineer can infer that the DUT would also pass a high-speed test carried out at the DUT's specified operating frequency. The invention therefore enables a low-speed tester to properly test a high-speed DUT of the type clocked by a single clock signal, even though the low-speed tester cannot operate at a frequency as high as the specified operating frequency of the DUT. A low-speed tester using the method of the present invention can test a circuit's ability to operate at a higher “effective frequency” than the tester's highest possible operating frequency.

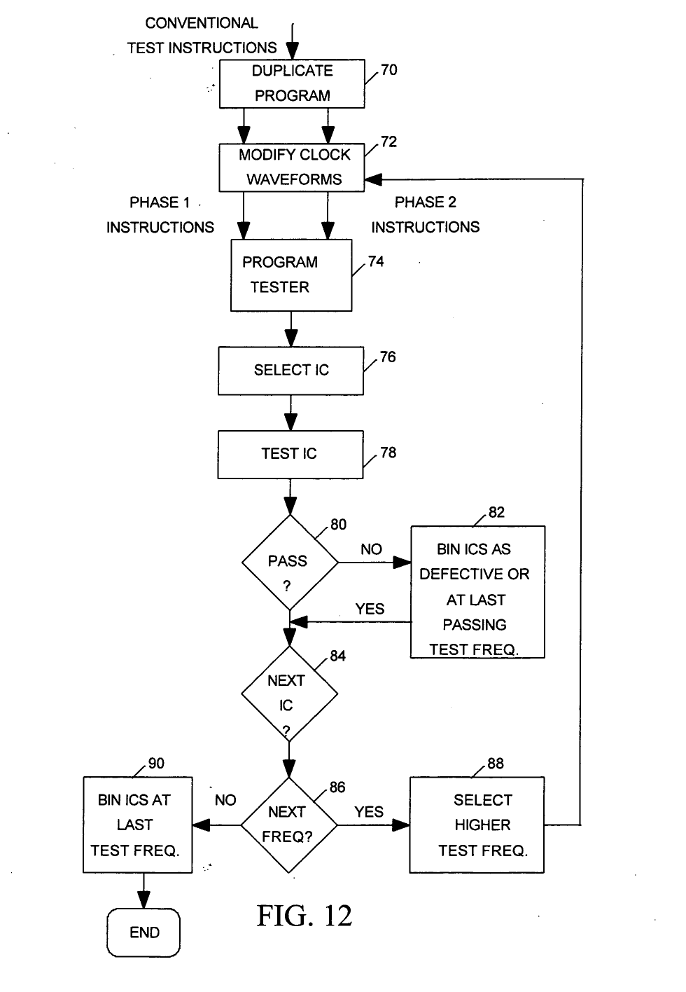

FIG. 12 is a data flow diagram illustrating steps of a process employing the method of the present invention for using a low-frequency tester to perform a binning test on a set of high-frequency integrated circuits to determine the highest frequency at which each IC can successfully operate. Initially, a test engineer creates a conventional program for an IC tester capable of performing a high-speed test of the IC at its lowest acceptable operating frequency, with the tester clocking the IC with a conventional clock signal having that particular frequency. Since the low-speed tester is not capable of operating at a sufficiently high frequency, it is necessary to convert the high-speed test program into a program enabling the tester to use the method of the present invention to test the IC. To do so the conventional instruction set is first duplicated (step 70) to produce two identical sets of instructions. At step 72 the first set of instructions is modified to produce instructions for Phase 1 of the test, wherein the clock signal exhibits the pattern of FIG. 9, and the second set of instructions is modified to produce instructions for Phase 2 of the test, wherein the clock signal exhibits the pattern of FIG. 10. The tester is then programmed using these instructions so that it performs the two phases of the test sequentially (step 74). A first IC to be tested is selected at step 76 to be tested at step 78. If the IC fails to pass the test (step 80), it is binned as defective, since it failed to operate at the lowest acceptable frequency. If a next IC has not been tested at the current frequency (step 84), it is selected (step 76), tested (step 78) and, if it fails the test, binned as defective (step 82). The process continues to loop through steps 76-84 testing each IC at the current low frequency until all ICs have been tested, with all ICs that fail the test binned as defective at step 82. When all ICs have been tested at the lowest effective frequency (step 84) and there is a next higher effective frequency at which to test the ICs (step 86), then the next higher effective frequency is selected (step 88) and the Phase 1 and Phase 2 waveforms are modified at step 72 to increase the effective frequency of the test. Referring to FIG. 11, this is done by advancing the timing of the clock signal pulses in the even numbered cycles of Phase 1 of the test and the odd-numbered cycles of Phase 2 of the test.

The tester is then reprogrammed to carry out the higher effective frequency test (step 74). The process then loops through steps 76-84 once for each IC to be tested at the higher effective frequency. Any IC that fails the test at that frequency is binned at step 82 at the next highest frequency for which it passed the test. When all ICs have been tested at that next higher frequency, a higher frequency is selected at step 88, the tester is reprogrammed to test at the hither effective frequency at steps 72 and 74, and all ICs that passed tests at lower frequencies are retested at the current effective frequency during repetitions of steps 76-84. The process continues to loop through steps 72-88 until the tester has tested ICs at the highest effective frequency of interest and no higher effective frequency test remains to be performed (step 86). The tester then bins the ICs that passed the last (highest) effective frequency test at that frequency (step 90).

The foregoing specification and the drawings depict exemplary embodiments of the best mode(s) of practicing the invention, and elements or steps of the depicted best mode(s) exemplify the elements or steps of the invention as recited in the appended claims. However, the appended claims are intended to apply to any mode of practicing the invention comprising the combination of elements or steps as described in any one of the claims, including elements or steps that are functional equivalents of the example elements or steps of the exemplary embodiment(s) of the invention depicted in the specification and drawings.

1. A method for testing a circuit to determine whether the circuit will operate properly when clocked at a specified clock period, the method comprising the steps of:
a. performing a first phase of a test on the circuit; and
b. performing a second phase of the test on the circuit,
wherein the first and second phases of the test comprise transmitting input signal patterns to the circuit, monitoring output signal patterns produced by the circuit in response to the input signals, and transmitting a clock signal to the circuit for clocking the circuit,
wherein each of the first and second phases of the test span a plurality of test cycles, with each test cycle spanning a uniform period exceeding the specified clock period, and
wherein a pulse of the clock signal is transmitted to the circuit during each test cycle with a delay following a start of each test cycle that alternates between a first delay and a second delay, the first delay differing from the second delay.

2. The method in accordance with claim 1,
wherein the first and second phases of the test each span N test cycles, 1 through N, where N is an integer greater than 3,
wherein during odd-numbered test cycles of the first phase of the test and even-numbered test cycles of the second phase of the test, a pulse of the clock signal is supplied to the circuit with the first delay following to the start of the test cycle,
wherein during even-numbered test cycles of the first phase of the test, and odd-numbered test cycles of the second phase of the test, a pulse of the clock signal is transmitted to the circuit with the second delay following the start of the test cycle.

3. The method in accordance with claim 2 wherein the first delay equals the specified clock period and the second delay exceeds the specified clock period.

4. The method in accordance with claim 2 wherein similar input signal patterns are transmitted to the circuit during the first and second phases of the test.

5. The method in accordance with claim 2 wherein steps a and b comprise the substeps of:
a1. generating a program for a programmable circuit tester, wherein the program describes a high-speed test spanning N test cycles that the circuit tester is to carry out on the circuit, wherein during each test cycle of the high-speed test, the tester is to transmit a pulse of the clock signal to the circuit with a particular delay following a start of each test cycle, wherein the particular delay is uniform all test cycles;
a2. modifying the program by modifying a manner in which it describes timing of clock signal pulses relative to the start of each test cycle to provide a first modified copy of the program for programming the programmable circuit tester to carry out the first phase of the test;
a3. modifying the program by modifying a manner in which it describes timing of clock signal pulses relative to the start of each test cycle to provide a second modified copy of the program for programming the programmable circuit tester to carry out the second phase of the test; and
a4. programming the programmable circuit tester with the first and second modified copies of the program so that the programmable circuit tester carries out the first and second phases of the test.

6. A method for testing a circuit to determine a highest clock frequency at which the circuit can operate, the method comprising the steps of:
a. specifying a clock period;
b. testing the circuit to determine whether the circuit will operate properly when clocked at the specified clock period, performing a first phase of a test, and a second phase of the test;
wherein the first and second phases of the test include transmitting input signal patterns to the circuit, monitoring output signal patterns produced by the circuit in response to the input signals patterns and transmitting a clock signal to the circuit for clocking the circuit,
wherein each of the first and second phases of the test span a plurality of test cycles with each test cycle spanning a uniform period exceeding the specified clock period,
wherein a pulse of the clock signal is transmitted to the circuit during each test cycle with a delay following a start of each test cycle that alternates between a first delay and a second delay,
wherein the first delay and the second delay differ; and
c. iteratively repeating steps a and b with the specified clock period being increased with each iteration of step a.

7. The method in accordance with claim 6
wherein the first and second phases of the test each span N test cycles, 1 through N, where N is an integer greater than 3,
wherein during odd-numbered test cycles of the first phase of the test and even-numbered test cycles of the second phase of the test, a pulse of the clock signal is transmitted to the circuit with the first delay following to the start of the test cycle, and
wherein during even-numbered test cycles of the first phase of the test, and odd-numbered test cycles of the second phase of the test, a pulse of the clock signal is transmitted to the circuit with the second delay following the start of the test cycle.

8. The method in accordance with claim 7 wherein similar input signal patterns are transmitted to the circuit during the first and second phases of the test carried out at step b.

9. The method in accordance with claim 7 wherein step b comprises the substeps of:
b1. generating a program for a programmable circuit tester, wherein the program describes a high-speed test spanning N test cycles that the circuit tester is to carry out on the circuit, wherein during each test cycle of the high-speed test, the tester is to transmit a pulse of the clock signal to the circuit with a particular delay following a start of each test cycle, wherein the particular delay is uniform all test cycles;
b2. modifying the program by modifying a manner in which it describes timing of clock signal pulses relative to the start of each test cycle to provide a first modified copy of the program for programming the programmable circuit tester to carry out the first phase of the test;
b3. modifying the program by modifying a manner in which it describes timing of clock signal pulses relative to the start of each test cycle to provide a second modified copy of the program for programming the programmable circuit tester to carry out the second phase of the test; and
b4. programming the programmable circuit tester with the first and second modified copies of the program so that the programmable circuit tester carries out the first and second phases of the test.

10. An apparatus for testing a circuit to determine whether the circuit will operate properly when clocked at a specified clock period, the apparatus comprising,
a programmable circuit tester for transmitting input signal patterns to the circuit, for monitoring output signal patterns produced by the circuit in response to the input signal patterns, and for transmitting a clock signal to the circuit for clocking the circuit; and
signal paths for conveying the input signal patterns, output signal patterns and the clock signal between the circuit tester and the circuit,
wherein the programmable circuit tester is programmed to carry out a first phase of a test, and a second phase of the test,
wherein each of the first and second phases of the test spans a plurality of test cycles with each test cycle spanning a uniform period exceeding the specified clock period, and
wherein the circuit tester transmits a pulse of the clock signal to the circuit during each test cycle of the first and second phases of the test with a delay following a start of the test cycle that alternates between a first delay and a second delay, wherein the first delay and the second delay differ.

11. The apparatus in accordance with claim 10
wherein each of the first and second phases of the test each spans N test cycles, 1 through N, where N is an integer greater than 3,
wherein during odd-numbered test cycles of the first phase of the test and even-numbered test cycles of the second phase of the test, a pulse of the clock signal is transmitted to the circuit with the first delay following to the start of the test cycle, and
wherein during even-numbered test cycles of the first phase of the test, and odd-numbered test cycles of the second phase of the test, a pulse of the clock signal is transmitted to the circuit with the second delay following the start of the test cycle.

12. The apparatus in accordance with claim 11 wherein the first delay equals the specified clock period and the second delay exceeds the specified clock period.

13. The apparatus in accordance with claim 11 wherein similar input signal patterns are transmitted to the circuit during the first and second phases of the test.

14. The apparatus in accordance with claim 11 wherein the programmable circuit tester is programmed by
generating a program describing a high-speed test spanning N test cycles, wherein during each test cycle of the high-speed test, the programmable circuit tester transmits a pulse of the clock signal to the circuit with a particular delay following a start of each test cycle; wherein the particular delay is uniform all test cycles,
modifying the program to provide a first modified copy of the program for programming the programmable circuit tester to carry out the first phase of the test by modifying a manner in which the program describes timing of clock signal pulses relative to the start of each test cycle;
modifying the program to provide a second modified copy of the program for programming the programmable circuit tester to carry out the second phase of the test by modifying a manner in which the program describes timing of clock signal pulses relative to the start of each test cycle; and
programming the programmable circuit tester with the first and second modified copies of the program so that the programmable circuit tester carries out the first and second phases of the test.

15. An apparatus for testing a circuit to determine a highest clock frequency at which the circuit can operate, the apparatus comprising:
a programmable circuit tester, for testing the circuit by carrying out a first phase of a test, and a second phase of the test;
wherein each of the first and second phases of the test span a plurality of test cycles, with each test cycle spanning a uniform period exceeding a specified clock period,
wherein during the first and second phases of the test, the programmable circuit tester transmits input signal patterns to the circuit, monitors output signal patterns produced by the circuit in response to the input signals patterns, and transmits a clock signal to the circuit for clocking the circuit,
wherein a pulse of the clock signal is transmitted to the circuit during each test cycle with a delay following a start of each test cycle that alternates between a first delay and a second delay, the first and second delays differing; and
a program compiler for programming the circuit tester to repeatedly perform the test with a different clock period being specified for each test.

16. The apparatus in accordance with claim 15
wherein the first and second phases of the test each span N test cycles, 1 through N, where N is an integer greater than 3,
wherein during odd-numbered test cycles of the first phase of the test and even-numbered test cycles of the second phase of the test, a pulse of the clock signal is transmitted to the circuit with the first delay following to the start of the test cycle,
wherein during even-numbered test cycles of the first phase of the test, and odd-numbered test cycles of the second phase of the test, a pulse of the clock signal is transmitted to the circuit with the second delay following the start of the test cycle.

17. The apparatus in accordance with claim 16 wherein the programmable test transmits similar input signal patterns to the circuit during the first and second phases of the test.
